(19) United States
(12) Patent Application Publication
(10) Pub. No.: US 2007/0096612 A1
(43) Pub. Date: May 3, 2007

(54) FLAT DISPLAY PANEL

(76) Inventors: Shi-Hao Li, Taipei County (TW); Hsia-Tsai Hsiao, Miao- Li Hsien (TW)

Correspondence Address: NORTH AMERICA INTELLECTUAL PROPERTY CORPORATION, P.O. BOX 506, MERRIFIELD, VA, 22116, US

(21) Appl. No.: 11/307,442

(22) Filed: Feb. 8, 2006

(30) Foreign Application Priority Data
Oct. 28, 2005 (TW) 094137835

(51) Int. Cl. H01J 61/40; H01J 5/16; H01K 1/26; H01K 1/30

(52) U.S. Cl. 313/112

(57) ABSTRACT

A flat display panel has a first substrate, a second substrate, a black matrix pattern being disposed on a surface of the second substrate in a non-display area, and a brightness enhancement sheet being disposed on a surface of the second substrate opposite to the first substrate; wherein the area ratio of the black matrix pattern to its corresponding pixel region is between 70% and 95%.

### BACKGROUND OF THE INVENTION

1. Field of the Invention

The present invention is related to a flat display panel, and more particularly, to a flat display panel comprising a black matrix pattern and a brightness enhancement sheet; wherein in each pixel region an area ratio of the black matrix pattern to the pixel region is between 70% and 95%.

2. Description of the Prior Art

An organic light emitting display device is one kind of electroluminescene (EL) display devices. The organic light emitting display has the advantages of high brightness, rapid reaction time, low power consumption, and wide viewing angle. It may replace liquid display devices and plasma display devices and become the main stream of the new generation flat display devices.

However, the internal part of the organic light emitting display device has conducting patterns or electrodes, which are made from metal. Thus, the organic light emitting display device has a problem of poor contrast. Therefore, the organic light emitting display device has to install a device to eliminate the environmental illumination and improve the poor contrast problem. Two main methods of conventional techniques for raising the contrast are illustrated as follows. The first conventional method is to dispose a polarizer on the surface of the substrate of the organic light emitting display device, for instance, a circular polarizer, to reduce the reflection of the environmental illumination. Although the polarizer may reduce the reflection of the environmental illumination, it may also reduce the transmission of light generated by the organic emitting display device itself to 43% only and result in poor efficiency of light emission. In order to attain sufficient brightness, it is necessary to increase the power consumption of the organic light emitting display device. The second conventional method is to install a black matrix pattern on the non-display area of the organic light emitting display device that may reduce the reflection of the environmental illumination. However, the black matrix disposed on the non-display area may reduce only part of the reflection, for example, the reflection of the environmental illumination resulted from the metal conducting wire and thin-film transistor. The reflection of the environment illumination coming from the cathode disposed in the display area is not reduced. Thus, the contrast of the organic light emitting display is still poor.

### SUMMARY OF THE INVENTION

The present invention provides a flat display panel with improved contrast of the flat display panel.

According to the claimed invention, a flat display panel is disclosed. The flat display panel comprises a first substrate; a second substrate divided into a plurality of pixel regions, each pixel region comprising a display area and a non-display area; a black matrix pattern disposed on a surface of the second substrate, the black matrix pattern being disposed on each non-display area of the second substrate; and a brightness enhancement sheet disposed on a surface of the second substrate opposite the first substrate; wherein in each pixel region an area ratio of the black matrix pattern to the pixel region is between 70% and 95%.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating an organic light-emitting display (OLED) panel according to a first preferred embodiment of the present invention. FIG. 2 is a schematic diagram illustrating an OLED panel according to a second embodiment.

FIG. 3 is a schematic diagram illustrating the distribution of a pixel region of the OLED panel according to the present invention.

FIG. 4 is a schematic diagram illustrating an OLED panel according to a third embodiment.

FIG. 5 is a schematic diagram illustrating an OLED panel according to a fourth embodiment.

### DETAILED DESCRIPTION

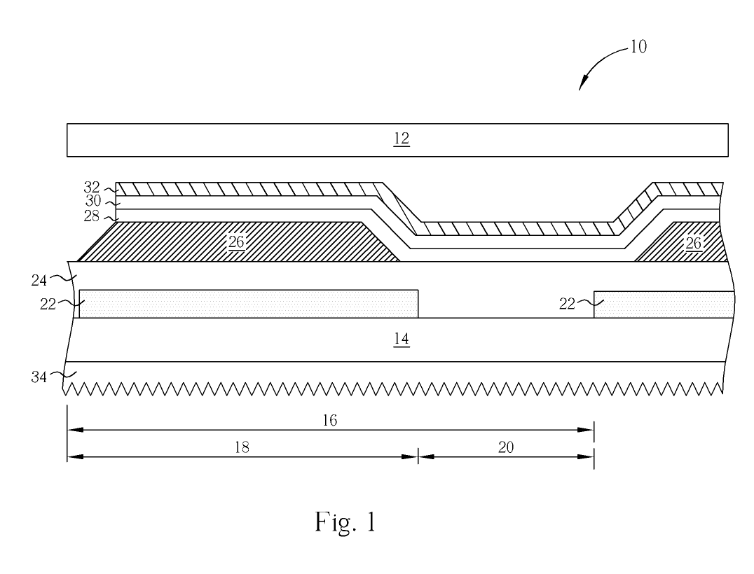

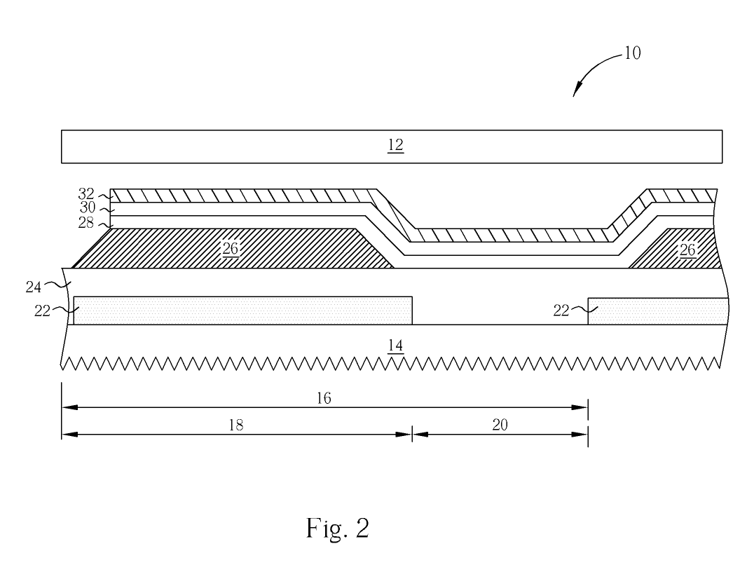

Please refer to FIG. 1. FIG. 1 is a schematic diagram illustrating an organic light-emitting display (OLED) panel according to a first preferred embodiment of the present invention; wherein only a single pixel region is presented to manifest the major characteristic of the present invention. As shown in FIG. 1, an OLED panel 10 of the present invention has a first substrate (upper substrate) 12 and a second substrate (lower substrate) 14. The first substrate 12 is connected with the second substrate 14 by a sealant (not shown in the diagram) to maintain a distance between two substrates. The OLED panel 10 is a rear-emission type display panel. Therefore, the second substrate 14 is a display panel and the second substrate 14 comprises a transparent material, such as glass, plastic, or quartz. The material of the first substrate may include a transparent material or an opaque material. The second substrate 14 has a plurality of pixel regions 16, and each pixel region 16 may be divided into a non-display area 18 and a display area 20. The OLED panel 10 comprises a black matrix pattern 22 disposed on a surface of the second substrate 14 facing the first substrate 12. As a result, it may reduce the reflection of the environmental illumination from the direction of the second substrate 14 to the first substrate 12; wherein the material of the black matrix pattern may include chromium, chromium oxide, chromium nitride or other materials with good anti-reflection properties. In addition, the surface of the second substrate 14 and the black matrix pattern 22 is covered with an inter-layer dielectric layer 24. A switch element 26, such as a thin-film transistor, is disposed on the inter-layer dielectric layer 24 in the non-display area 18. Moreover, a pixel electrode (anode) 28, an organic light-emitting layer 30, and a cathode (reflective electrode) 32 are stacked on the switch element 26 and inter-layer dielectric layer 24; wherein the pixel electrode 28 is a transparent electrode and electrically connected to the switch element 26. The organic light-emitting layer 30 includes organic light-emitting materials and is powered by the pixel electrode 28 and the cathode 32.

The cathode 32 of the OLED panel 10 comprises materials with high-reflective properties, such as metal, that reflects the light generated by the organic light-emitting layer 30 and raises the brightness. However, the cathode 32 may also reflect the environmental illumination from the direction of the second substrate 14 and affect the contrast of the OLED panel 10. Therefore, the major characteristic of the present invention is to raise the area ratio of the non-display area; in other words, the area ratio of the display area 20 may be reduced correspondingly. Thus, in the display area 20, the environmental illumination reflected by the cathode 32 may be reduced and the contrast of the OLED panel 10 may be raised effectively. Because the reduction of the display area 20 may also result in the reduction of the brightness of the OLED panel 10 itself. For this reason, the OLED panel 10 of the present invention further comprises a brightness enhancement sheet 34 disposed on a surface of the second substrate 14 opposite to the first substrate 12 to improve the brightness of the OLED panel 10; wherein the brightness enhancement sheet 34 may be brightness enhancement film (BEF) or dual brightness enhancement film (DBEF) as required. Depending on the different kinds of the brightness enhancement sheet 34, the surface of the brightness enhancement sheet 34 may include patterns capable of guiding light, such as a round-shape lens pattern, a trench pattern or a pyramid pattern. In addition, the brightness enhancement sheet 34 may be a multi-layer interference thin-film or any other available structure to enhance brightness.

According to the first embodiment, the brightness enhancement sheet 34 is attached to the surface of the second substrate 14, as shown in FIG. 1. The application of the claimed invention is not limited to the present embodiment. The brightness enhancement sheet may be formed on the second substrate 13 by other methods. Please refer to FIG. 2. FIG. 2 is a schematic diagram illustrating an OLED panel according to a second embodiment. In order to more easily distinguish the difference between the present embodiment and the above-mentioned embodiment, the same elements of FIG. 2 use the same notation as the first embodiment. As shown in FIG. 2, the brightness enhancement sheet 34 of the OLED panel 10 of the second embodiment is fabricated directly on the surface of the second substrate 14. For instance, the method of fabricating the brightness enhancement sheet 34 may use chemical processes such as etching, or mechanical processes such as sand blasting. Both are different from the attachment of the brightness enhancement sheet 34 of the first embodiment.

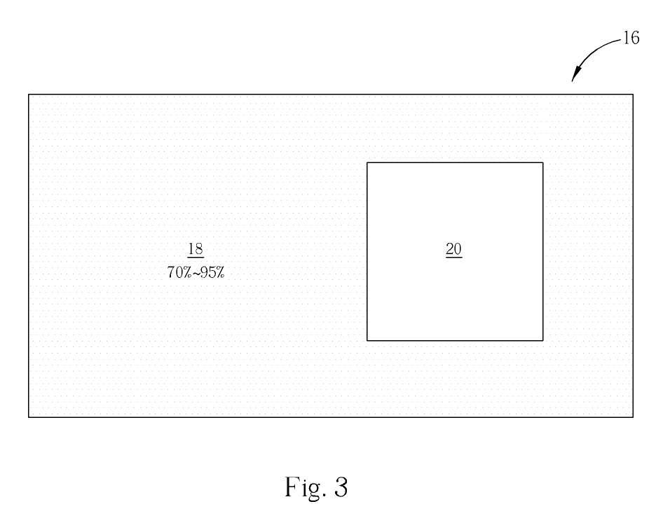

Please refer to FIG. 3 (also FIG. 1 and FIG. 2). FIG. 3 is a schematic diagram illustrating the distribution of a pixel region of the OLED panel according to the present invention. As shown in FIG. 2, the pixel area 16 of the OLED panel 10 comprises a non-display area 18 and a display area 20, wherein in each pixel region an area ratio of the non-display area 18 to the pixel region 16 is between 70% and 95%. That means the area ratio of the black matrix pattern 22 to the total pixel region 16 is between 70% and 95%. In coordination with the disposition of brightness enhancement sheet 34, the reflection of the environmental illumination is reduced and the brightness of the OLED panel 10 is maintained. Moreover, the shapes of the non-display area 18 and the display area 20 are not limited. It may be modified according to different designs of the OLED panel 10.

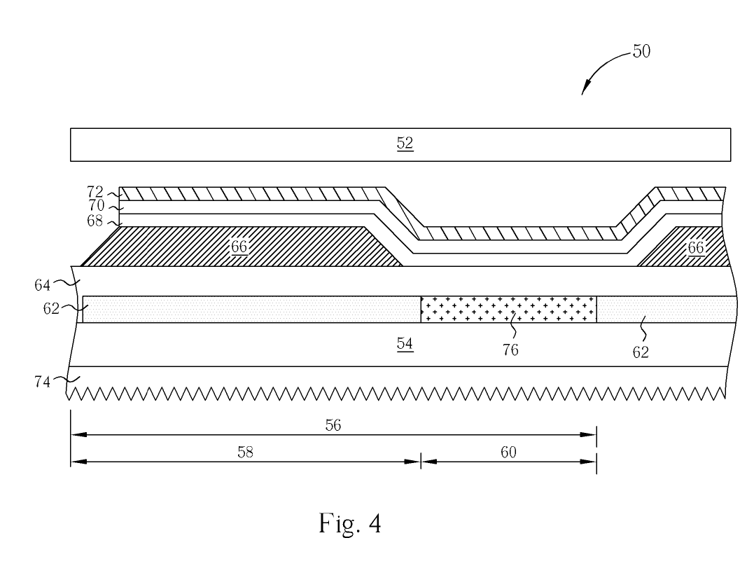

Please refer to FIG. 4. FIG. 4 is a schematic diagram illustrating an OLED panel according to a third embodiment. As shown in FIG. 4, the OLED panel 50 of the claimed invention comprises a first substrate (upper substrate) 52 and a second substrate (lower substrate) 54; wherein the second substrate 54 includes a plurality of pixel regions 56 and each pixel region 56 comprises a non-display area 58 and a display area 60. The OLED panel 50 comprises a black matrix pattern 62, which is disposed on a surface of the second substrate 54 facing the first substrate 52. The black matrix pattern 62 may reduce the reflection of the environmental illumination from the direction of the second substrate 54 to the first substrate 52. In addition, in the display area 60, a surface of the second substrate 54 further comprises a color filter pattern 76. An inter-layer dielectric layer 64 is covered on the surface of the color filter pattern 76 and the black matrix pattern 62. In the non-display area 58, a switch element 66 such as a thin-film transistor, is disposed above the inter-layer dielectric layer 64. In addition, a pixel electrode (anode) 68, an organic light-emitting layer 70 and a cathode (reflective electrode) 72 are stacked on the switch element 66 and the inter-layer dielectric layer 64. Moreover, the OLED panel 50 further comprises a brightness enhancement sheet 74 disposed on a surface of the second substrate 54 opposite to the first substrate 54. The brightness enhancement sheet 74 may raise the brightness of the OLED panel 50.

Similar to the above-described embodiments, according to the OLED panel 50 of the third embodiment, the area ratio of the non-display area 58 to the pixel region 56 is between 70% and 95%. That means the area ratio of the black matrix pattern 62 to the pixel region 56 is between 70% and 95%. Different from the above-described embodiments, in the display area 60, a color filter pattern 76 is disposed on the surface of the second substrate 54. The function of the color filter 76 is to absorb a part of the environmental illumination illuminating to the display area 60. For instance, if the color filter pattern 76 is a blue filter pattern, the environmental illumination (white light) in the range of the red-light wavelength may be absorbed. Thus, it may reduce the environmental illumination illuminating to the display area 60, and may further reduce the environmental illumination reflected by the cathode 72 in the display area 60. These factors may raise the contrast of the OLED panel 50.

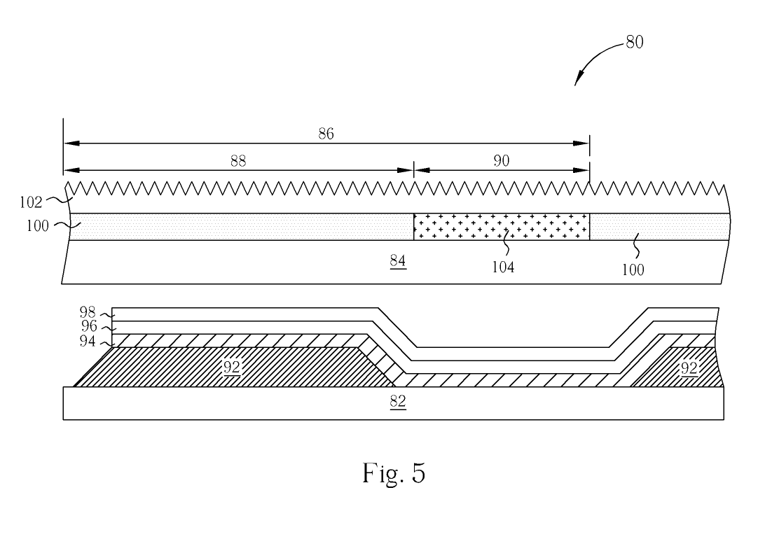

Please refer to FIG. 5. FIG. 5 is a schematic diagram illustrating an OLED panel according to a fourth embodiment. As shown in FIG. 5, the OLED panel 80 of the present invention comprises a first substrate (lower substrate) 82 and a second substrate (upper substrate) 84. The first substrate 82 is connected to the second substrate 84 by a sealant (not shown in the diagram) to maintain a distance between two substrates. The OLED panel 80 of the present embodiment is a front-emission type panel; thus, the second substrate 84 comprises a transparent material, such as glass, plastic or quartz. The material of the first substrate 82 may comprise transparent material or opaque glass. The second substrate 84 comprises a plurality of pixel regions 86 and each pixel region 86 may be divided into a non-display area 88 and a display area 90. In the non-display area 88, a switch element 92 such as a transistor, is disposed on the first substrate 82. Furthermore, in the display area 90, a pixel electrode 94, an organic light-emitting layer 96 and a cathode 98 are stacked on the switch element 92 and the first substrate 82. Because the OLED panel 80 of the third embodiment is a front-emission type panel, the pixel electrode 94 comprises materials with high-reflective properties such as metal, to reflect the light generated by organic light-emitting layer 96 and to raise the brightness. The cathode 98 comprises transparent conductive material.

Moreover, in the non-display area 88, a black matrix pattern 100 is installed on the second substrate 84. The black matrix pattern 100 further comprises a brightness enhancement sheet 102. Inside the display area 90, a color filter pattern 104 may be disposed selectively on the second substrate 84. What distinguishes the present embodiment from the above-mentioned embodiment is that the OLED panel 80 is a front-emission type panel. Thus, the black matrix pattern 100, the brightness enhancement sheet 102, and the color filter 104 are installed on different locations. However, the OLED panel 80 has the same characteristic of the area ratio of the non-display area 88 to the pixel region 86 being between 70% and 95%. Functions of the black matrix pattern 100, the brightness enhancement sheet 102, and the color filter pattern 104 are described above.

In conclusion, the major characteristic of the OLED panel of the present invention is to control the area ratio of the black matrix pattern to the pixel region to be between 70% and 90%. In coordination with the brightness enhancement sheet, the contrast of the OLED panel is raised without affecting the brightness. The characteristic of the present invention is the distribution of the display area and the non-display area, and the use of the brightness enhancement sheet. Therefore, other designs of the OLED panel, for example, the composition of the light emitting diode and the material of the electrode may be modified according to the present technique. In addition, the above-mentioned embodiments are illustrated by the example of the OLED panel, but the flat display panel according to the claimed invention is not limited to the OLED panel only.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A flat display panel comprising:
a first substrate;
a second substrate opposing to the first substrate and divided into a plurality of pixel regions, each pixel region having a display area and a non-display area;
a black matrix pattern disposed on each non-display area of the second substrate; and
a brightness enhancement sheet disposed on a surface of the second substrate opposite the first substrate,
wherein the area ratio of the black matrix pattern to the pixel region is between about 70% and about 95% in each pixel region.

2. The flat display panel of claim 1, wherein the black matrix pattern is disposed on a surface of the second substrate facing the first substrate.

3. The flat display panel of claim 1, further comprising a color filter pattern disposed on a surface of the second substrate facing the first substrate, the color filter pattern being disposed on each display area.

4. The flat display panel of claim 1, wherein the black matrix pattern is disposed on a surface of the second substrate opposite the first substrate.

5. The flat display panel of claim 1, further comprising a color filter pattern disposed on a surface of the second substrate opposite the first substrate, the color filter pattern being disposed on each display area.

6. The flat display panel of claim 1, wherein the brightness enhancement sheet is attached to the second substrate.

7. The flat display panel of claim 1, wherein the brightness enhancement sheet is formed on the second substrate.

8. The flat display panel of claim 1, wherein the surface of the second substrate opposite the first substrate is a display surface.

9. The flat display panel of claim 1, further comprising an organic light emitting device positioned in each pixel region.
